(19) United States
(12) Patent Application Publication
(10) Pub. No.: US 2026/0020236 A1
(43) Pub. Date: Jan. 15, 2026

(54) THREE-DIMENSIONAL CHARGE TRAPPING NOR FLASH MEMORY ARCHITECTURES

(71) Applicant: Micron Technology, Inc., Boise, ID (US)

(72) Inventors: Agostino Pirovano, Milano (IT); Innocenzo Tortorelli, Cernusco Sul Naviglio (IT); Fabio Pellizzer, Boise, ID (US); Lorenzo Fratin, Buccinasco (IT)

(21) Appl. No.: 19/243,550

(22) Filed: Jun. 19, 2025

Related U.S. Application Data
(60) Provisional application No. 63/670,024, filed on Jul. 11, 2024.

(51) Int. Cl. H10B 43/20; H10B 43/10; H10B 43/30

(52) U.S. Cl. CPC H10B 43/20; H10B 43/10; H10B 43/30

(57) ABSTRACT

Methods, systems, and devices for charge trapping NOR Flash memory architectures are described. A memory device may include a pier positioned between a first pillar and a second pillar, where the pier includes multiple first memory cells at a first end of the pier and multiple second memory cells at a second end of the pier. The first pillar may be coupled with the pier via multiple first conductive paths and the second pillar may be coupled with the pier via multiple second conductive paths, where each first conductive path couples a respective first and second memory cell with the first pillar and each second conductive path couples a respective first and second memory cell to the second pillar. The memory device may include multiple first word lines each coupled with a respective first memory cell and include multiple second word lines each coupled with a respective second memory cell.

### CROSS REFERENCE

The present application for patent claims priority to U.S. Patent Application No. 63/670,024 by Pirovano et al., entitled “THREE-DIMENSIONAL CHARGE TRAPPING NOR FLASH MEMORY ARCHITECTURES,” filed Jul. 11, 2024, which is assigned to the assignee hereof, and which is expressly incorporated by reference in its entirety herein.

### TECHNICAL FIELD

The following relates to one or more systems for memory, including three-dimensional charge trapping NOR Flash memory architectures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), Flash memory, phase change memory (PCM), 3-dimensional cross-point memory (3D cross point), NOR and NAND Flash memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NOR Flash) may maintain their programmed states for extended periods of time even in the absence of an external power source.

### BRIEF DESCRIPTION OF THE DRAWINGS

FIG. 1 shows an example of a system that supports three-dimensional (3D) charge trapping NOR Flash memory architectures in accordance with examples as disclosed herein.

FIG. 2 shows an example of a memory device that supports 3D charge trapping NOR Flash memory architectures in accordance with examples as disclosed herein.

FIG. 3 shows cross sectional views of a memory device that supports 3D charge trapping NOR Flash memory architectures in accordance with examples as disclosed herein.

FIG. 4 shows an example of a memory cell that supports 3D charge trapping NOR Flash memory architectures in accordance with examples as disclosed herein.

FIG. 5A shows an example of a processing step that supports 3D charge trapping NOR Flash memory architectures in accordance with examples as disclosed herein.

FIG. 5B shows an example of a processing step that supports 3D charge trapping NOR Flash memory architectures in accordance with examples as disclosed herein.

FIG. 5C shows an example of a processing step that supports 3D charge trapping NOR Flash memory architectures in accordance with examples as disclosed herein.

FIG. 5D shows an example of a processing step that supports 3D charge trapping NOR Flash memory architectures in accordance with examples as disclosed herein.

FIG. 5E shows an example of a processing step that supports 3D charge trapping NOR Flash memory architectures in accordance with examples as disclosed herein.

FIG. 6 shows an example of a memory device that supports 3D charge trapping NOR Flash memory architectures in accordance with examples as disclosed herein.

FIG. 7 shows an example of a memory device that supports 3D charge trapping NOR Flash memory architectures in accordance with examples as disclosed herein.

FIG. 8 shows a flowchart illustrating a method or methods that support 3D charge trapping NOR Flash memory architectures in accordance with examples as disclosed herein.

### DETAILED DESCRIPTION

Some memory devices may be utilized for artificial intelligence (AI) applications. Such AI applications may involve increased read accesses within the memory device, where such read access may be associated with various latency metrics. Additionally, such AI applications may involve storing a relatively large quantity of data within the memory device. In such cases, however, read latencies associated with some memory devices may not satisfy the latency metrics for AI applications. For example, some AI applications may include large numbers of read operations in quick succession. Alternatively, some memory devices may not have sufficient memory density (e.g., sufficient storage capacity) to store the increased quantity of data for AI applications, may not be cost effective, or both. For example, dynamic random access memory (DRAM) devices may be associated with read performances that satisfy the various latency metrics for AI applications, however, such DRAM devices may be associated with an increased cost and have a relatively lower memory density (e.g., reduced storage capacity) as compared to other devices. Alternatively, three dimensional (3D) NAND devices may be cost effective and have sufficient memory density for AI applications. However, such 3D NAND devices may be associated with increased read latency as compared to other systems, which may be insufficient for AI applications. Thus, memory solutions that provide for a higher memory density, while providing increased read performance at a lower cost may be desired.

The techniques, methods, and devices described herein may provide for the use and manufacture of a memory device that implements a 3D charge trapping NOR Flash memory architecture, which may provide for improved read performances and increased memory density, while also being cost-effective. For example, the memory device may include a pier and pillar architecture to increase the density of memory cells within the memory device, while also reducing costs. Additionally, by utilizing charge trapping NOR memory cells, the read latency associated with accessing such memory cells may be reduced relative to other memory cells (e.g., 3D NAND memory cells). In such examples, the memory device may include multiple piers, where each pier may include multiple first memory cells at a first end of the pier, and multiple second memory cells at a second end of the pier. To increase the memory density of the memory device, each first memory cell and each second memory cell may be configured to store two bits of data (e.g., a respective bit at each end of the memory cell).

Each pier may be positioned between a first pillar and a second pillar and be coupled with the first and second pillar via respective conductive paths, where such pillars may be utilized to access the memory cells at each pier. For example, the first and second pillars may be configured as selectable source and drain lines, such that to access a first bit of a first memory cell, the first pillar may be selected as the source and biased to a first voltage, while the second pillar may be selected as the drain and biased to a second voltage. Alternatively, to read the second bit of the first memory cell, the first pillar may be selected as the drain and biased to the second voltage, while the second pillar may be selected as the source and biased to the first voltage. By utilizing such pier and pillar architectures, the memory device may experience reduced latency during read accesses, while increasing the memory density and reducing the cost of the memory device.

In addition to applicability in memory systems as described herein, techniques for 3D charge trapping NOR Flash memory architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems, devices, and circuits. Features of the disclosure are further illustrated and described in the context of memory devices, processing steps, and flowcharts.

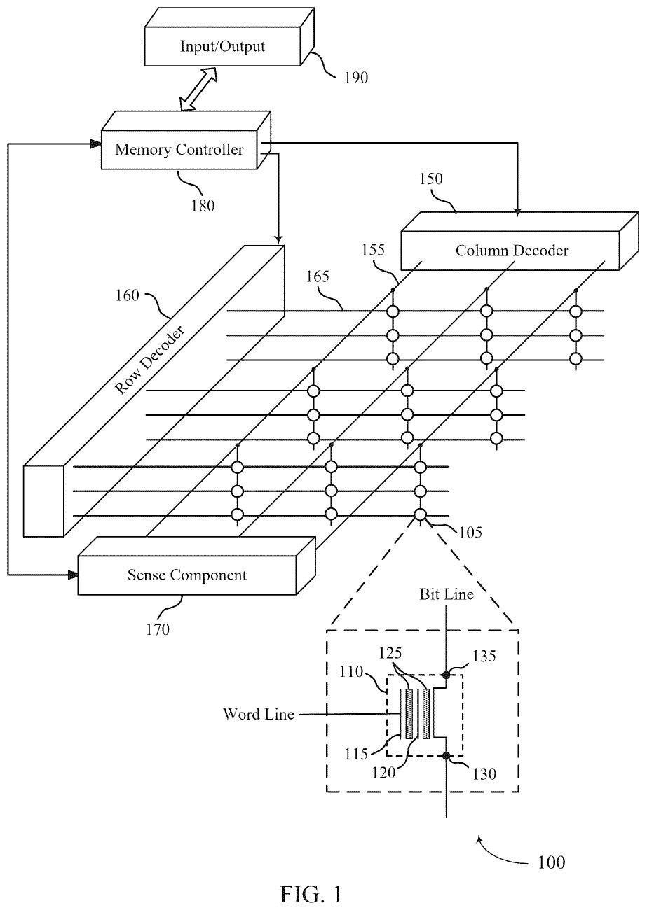

FIG. 1 shows an example of a memory device 100 that supports 3D charge trapping NOR Flash memory architectures in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

Developments in AI applications may lead to a memory solution that is capable of providing a high density memory array combined with improved read performance (e.g., reduced latency and increased bandwidth) at a low cost, without increased write performances. AI applications may involve increased read operations having reduced latency metrics as compared to other applications, while also involving storing an increased quantity of data within a memory device. Accordingly, read latencies associated with some other memory devices may not satisfy the latency metrics for AI applications. Alternatively, some memory devices may not have sufficient memory density (e.g., sufficient storage capacity) to store the increased quantity of data for AI applications, may not be cost effective, or both.

For example, DRAM memory devices may have a read performance that satisfies the latency and bandwidth metrics of such AI applications. However, such DRAM memory devices may be limited in memory density, not be cost effective, and involve an increased idle power to maintain the data. Alternatively, 3D NAND devices may provide for increased memory density (as compared to DRAM) and be cost effective. However, such 3D NAND devices may have increased latency due to the inherent string architecture utilized in 3D NAND systems, thereby being insufficient for AI applications. Some memory devices may utilize planar NOR memory cells, where such memory devices may have increased reading performances (e.g., similar to those of DRAM, but lacking in write performance and endurance) and provide an inherent advantage of non-volatility. Accordingly, a high-density NOR-like Flash memory may be utilized for AI applications (e.g., neural network executions).

According to the techniques described herein, the memory device 100 may include multiple charge trapping NOR Flash memory cells 105 in a pier and pillar architecture to increase the memory density (e.g., similar to 3D NAND three-bit-per-cell density) within the memory device 100 and improve read performance (e.g., have a relatively quicker random access speed, utilize decreased read voltages, have a higher bandwidth, among other advantages), while also reducing costs. For example, the memory device 100 may include multiple piers, where each pier may include multiple first memory cells 105 at a first end of the pier, and multiple second memory cells 105 at a second end of the pier.

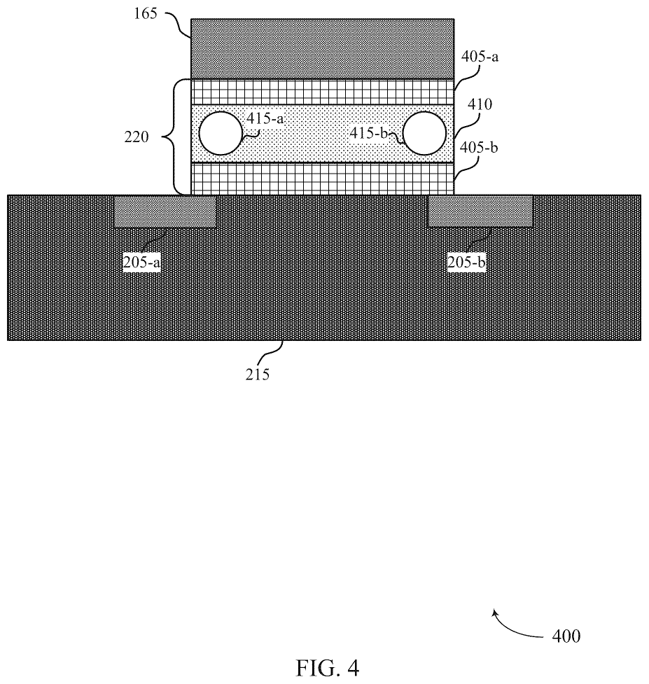

To further increase the density (e.g., storage capacity) of the memory device 100, each memory cell 105 may be configured to store one or more bits of information. For example, each memory cell 105 may be configured as a single-level cell (SLC) to store a single bit of data or as a cell that stores two or more bits of data. For example, a memory cell 105 may be configured as a multi-level cell (MLC) that stores two bits of data, a triple-level cell (TLC) that stores three bits of data, a quad-level cell (QLC) that stores four bits of data, or a penta-level cell (PLC) that stores five bits of data. FIG. 1 illustrates a charge trapping NOR Flash memory cell 105 that includes a structure 110 that may be used to store two bits of data. The structure 110 may include a control gate 115 and a charge trapping structure 120, where the charge trapping structure 120 may, in some examples, be between two portions of dielectric material 125. The structure 110 also may include a first node 130 (e.g., a source or drain) and a second node 135 (e.g., a drain or source). One or more logic values may be stored in the memory cell 105 by storing (e.g., writing) a quantity of electrons (e.g., an amount of charge) on the charge trapping structure 120. That is, the memory cell 105 may be programmed by trapping hot electrons into the charge trapping structure 120, where such electrons may be generated through channel-hot-electron mechanisms. Such charge trapping may occur at either side of the charge trapping structure 120 (e.g., at a first side to store a first bit of information and at a second side to store a second bit of information), thereby creating two bits of data store per memory cell 105. The memory cell 105 may be further described herein with reference to FIG. 4.

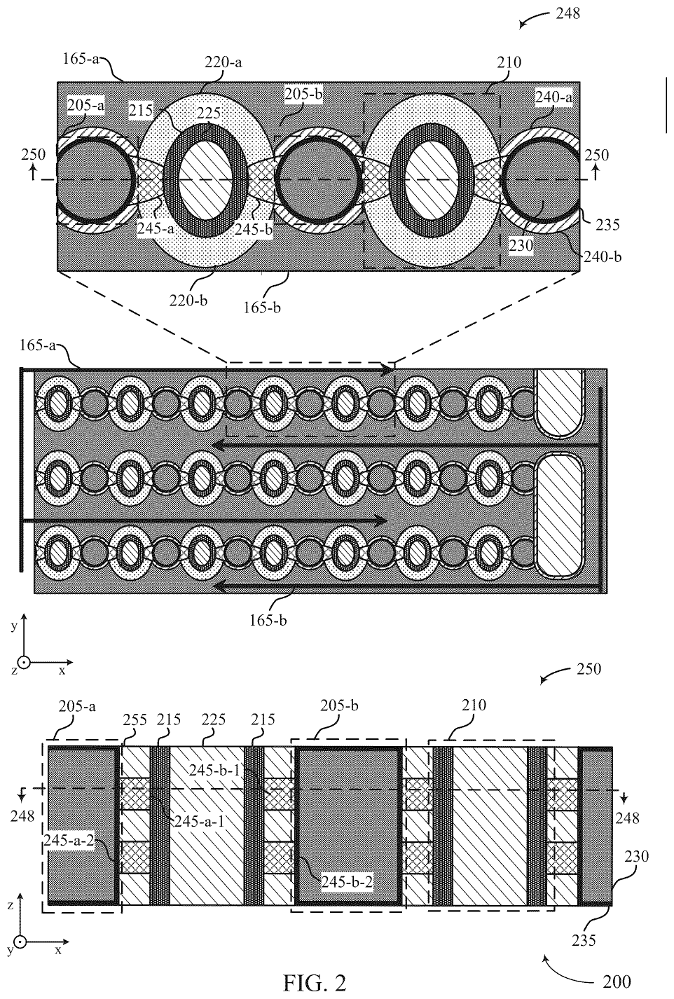

Piers and pillars may be positioned in a two dimensional array, where each pier may be positioned between a first pillar and a second pillar and be coupled with the first and second pillar via respective conductive paths, where such pillars may be utilized to access the memory cells at each pier. Each respective first memory cell 105 and each respective second memory cell 105 of a pier may be connected to a corresponding word line 165, where such word lines 165 may be utilized to access one of the multiple first memory cells or one of the multiple second memory cells. Each row of pillars may be connected to a respective source/drain (S/D) line (not shown) via a first transistor (thin film transistor) and each first transistor along each column of pillars may be connected to a corresponding bit line 155 (e.g., digit line or gate line). Accordingly, the S/D lines (e.g., access lines) may be perpendicular to the bit lines 155 (e.g., gate lines). Such pier and pillar architecture may be further described herein with reference to FIGS. 1 and 2.

To access a memory cell 105, the column decoder 150 (e.g., gate line decoder) and a S/D decoder (not shown) may select the target memory cell 105 during programming (e.g., writing) or reading by biasing a single bit line 155 and two adjacent S/D lines, while the row decoder 160 may bias a word line 165 that corresponds to the memory cell 105. For example, the column decoder may activate a bit line 155, thereby selecting a column of pillars. Accordingly, the S/D decoder may select two adjacent S/D lines, thereby selecting a target pier, which may be positioned between the two selected pillars on the selected column. Further, the row decoder 160 may bias the word line 165 that corresponds to the target memory cell 105.

As described herein, each pillar coupled with the target pier may be configured as a source or a drain based on which bit within the target cell the memory device is to access. As such, to access a first bit of the target memory cell 105, the S/D decoder may configure the first pillar as a source by biasing the first pillar to a first voltage and may configure the second pillar as a drain by biasing the second pillar to a second voltage. Alternatively, to access the second bit of the target memory cell 105, the S/D decoder may configure the first pillar as a drain by biasing the first pillar to the second voltage and may configure the second pillar as a source by biasing the second pillar to the first voltage. Techniques to access the memory cells 105 may be further described herein with reference to FIG. 4.

A memory controller 180 may control the operation (e.g., read, write, re-write, refresh) of memory cells 105 through the various components (e.g., row decoder 160, column decoder 150, sense component 170, S/D decoder) and interface with an input/output function 190 (e.g., such as a host system). In some cases, one or more of a row decoder 160, a column decoder 150, a sense component 170, and a S/D decoder may be co-located with a memory controller 180. A memory controller 180 may generate row and column address signals in order to activate a desired word line 165, bit line 155, and adjacent S/D lines. In some examples, a memory controller 180 may generate and control various voltages or currents used during the operation of memory device 100.

FIG. 2 shows an example of a memory device 200 that supports 3D charge trapping NOR Flash memory architectures in accordance with examples as disclosed herein. Aspects of the memory device 200 may implement, or be implemented by, aspects of the memory device 100. For example, the memory device 200 may include one or more charge trapping NOR Flash memory cells 105 configured in a pier and pillar architecture, as described herein with reference to FIG. 1. The memory device 200 may provide for increased memory density and improved read performances.

With respect to the top view 248, the memory device 200 may include multiple piers 210 formed into a stack of materials that alternates between word lines 165 and oxide layers 255, where each pier 210 may be positioned between a respective pair of pillars 205 (e.g., forming a comb like structure in the word lines 165). For example, a pier 210 may be positioned between a pillar 205-a (e.g., first pillar) and a pillar 205-b (e.g., a second pillar). Each pier 210 may include memory cells 220-a (e.g., charge trapping NOR Flash memory cells 105) at a first end of the pier 210 (e.g., in the y direction), where the memory cells 220-a extend along the z direction of the memory device 200 and each memory cell 220-a may be coupled with a respective word line 165 (e.g., an even or odd word line). Similarly, each pier 210 may include memory cells 220-b at a second end of the pier 210 (e.g., in the y direction), where the memory cells 220-a extend along the z direction of the memory device 200 and each memory cell 220-b may be coupled with a respective word line 165 (e.g., an even or odd word line based on the position of the pier 210 within the memory device 200).

Each pier 210 may further include a conductive layer 215 (e.g., p-type poly-silicon) that is coupled with an inner surface of each memory cell 220-a of multiple memory cells 220-a and is coupled with an inner surface of each memory cell 220-b of multiple memory cells 220-b. Additionally, each pier 210 may include a core dielectric material 225 (e.g., a multi-stack dielectric composed by silicon oxide, silicon nitride, silicon oxide layers, or a combination thereof) that is coupled with an inner surface of the conductive layer 215.

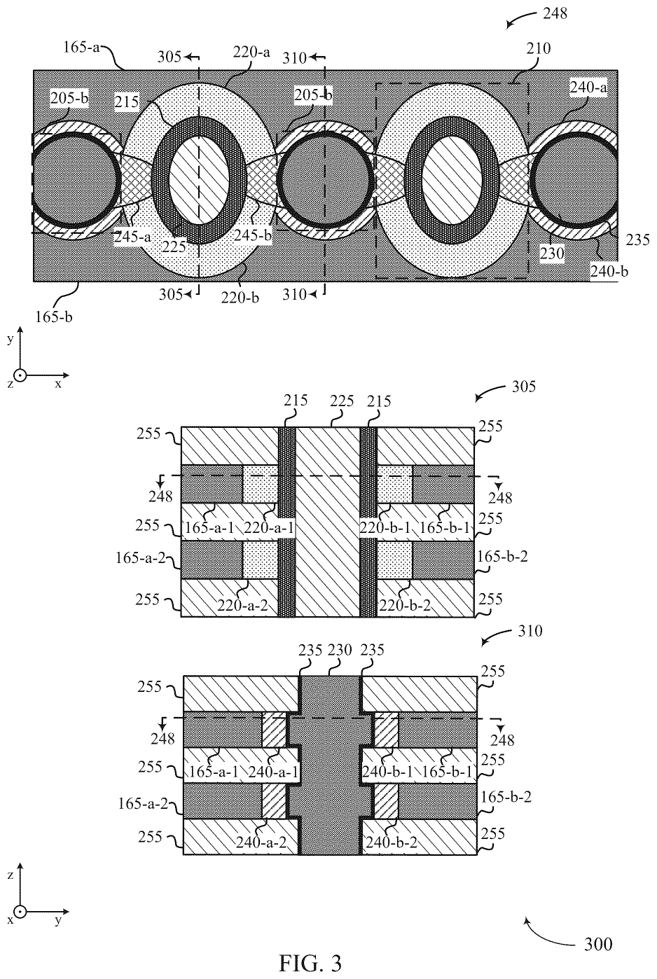

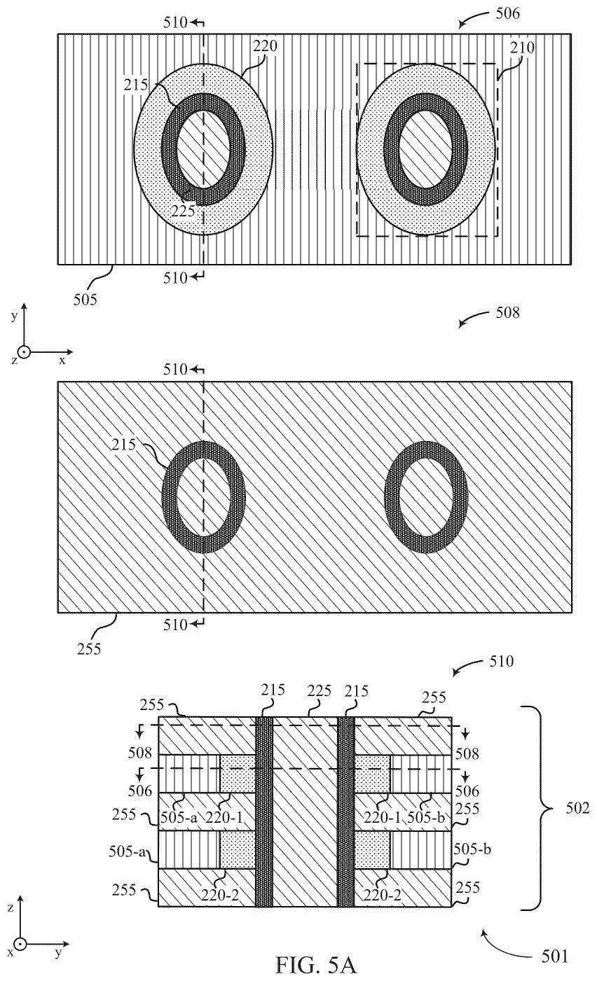

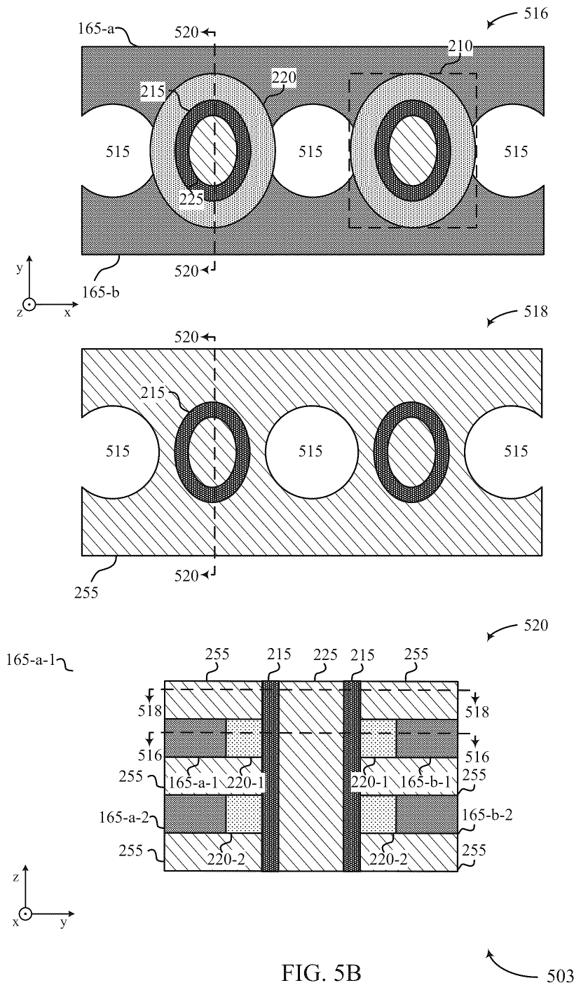

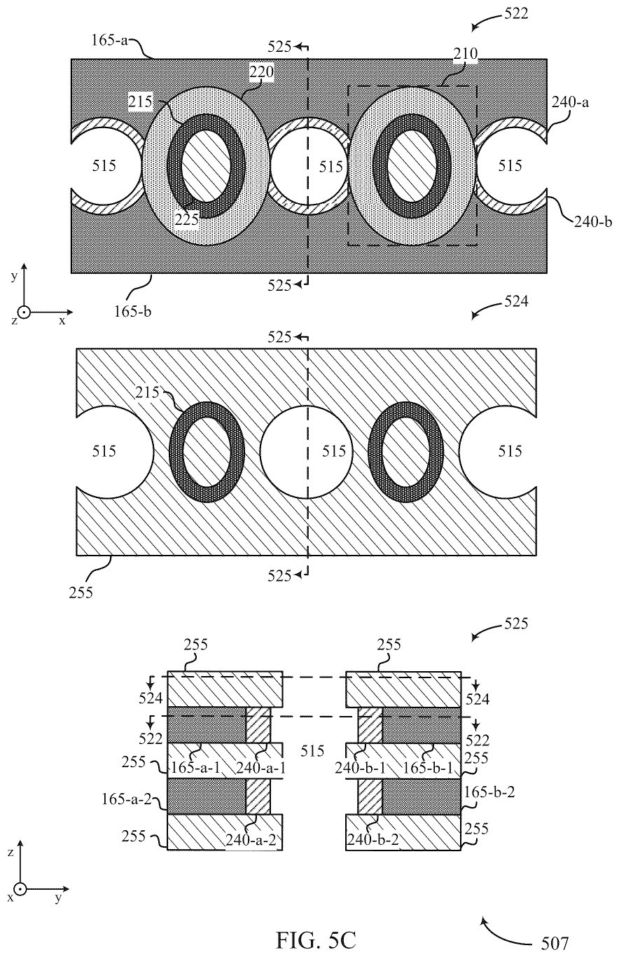

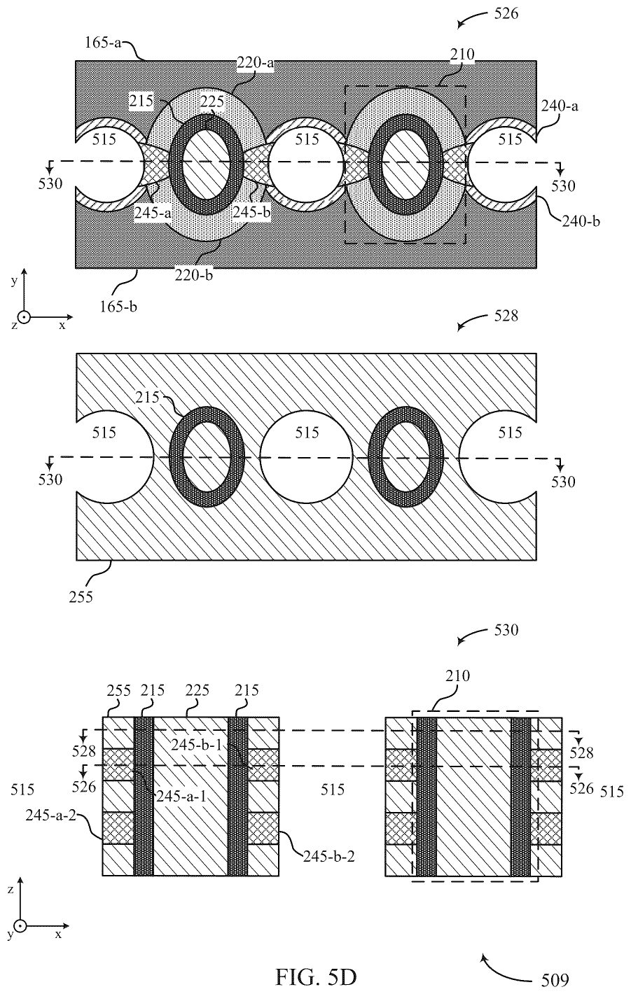

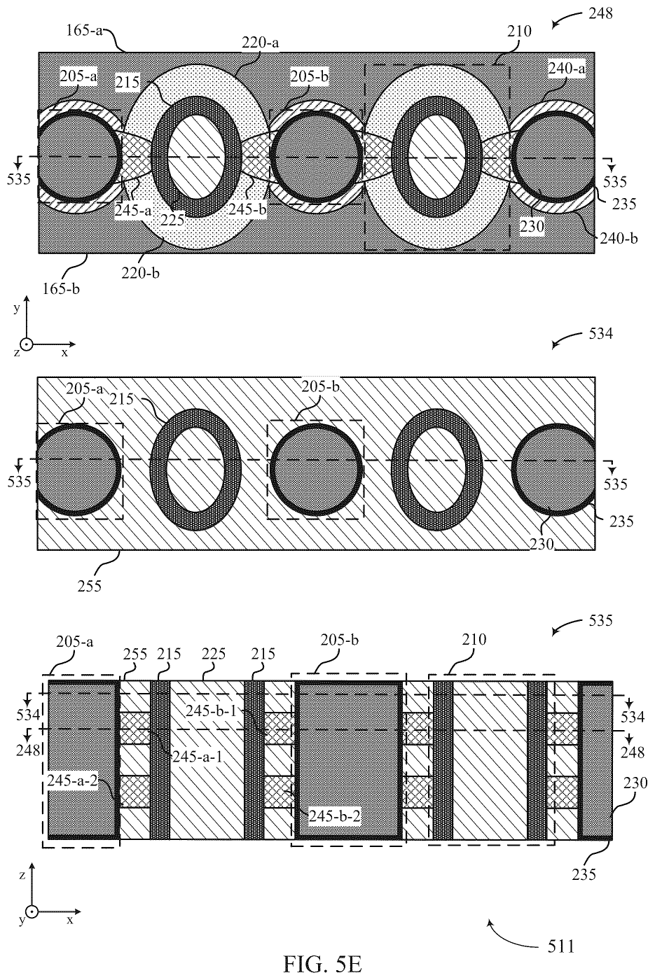

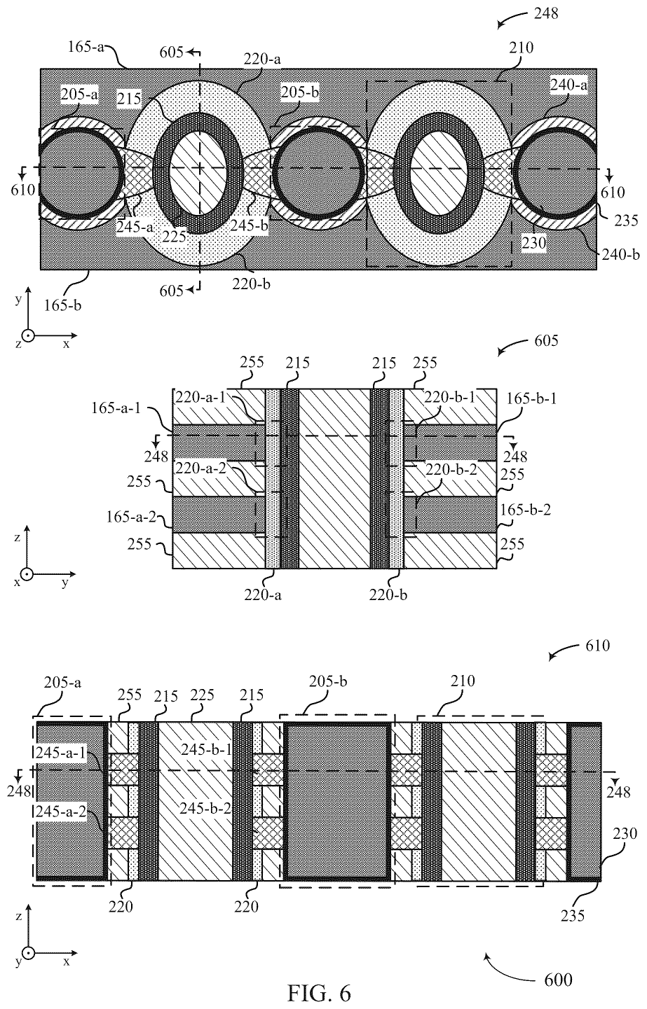

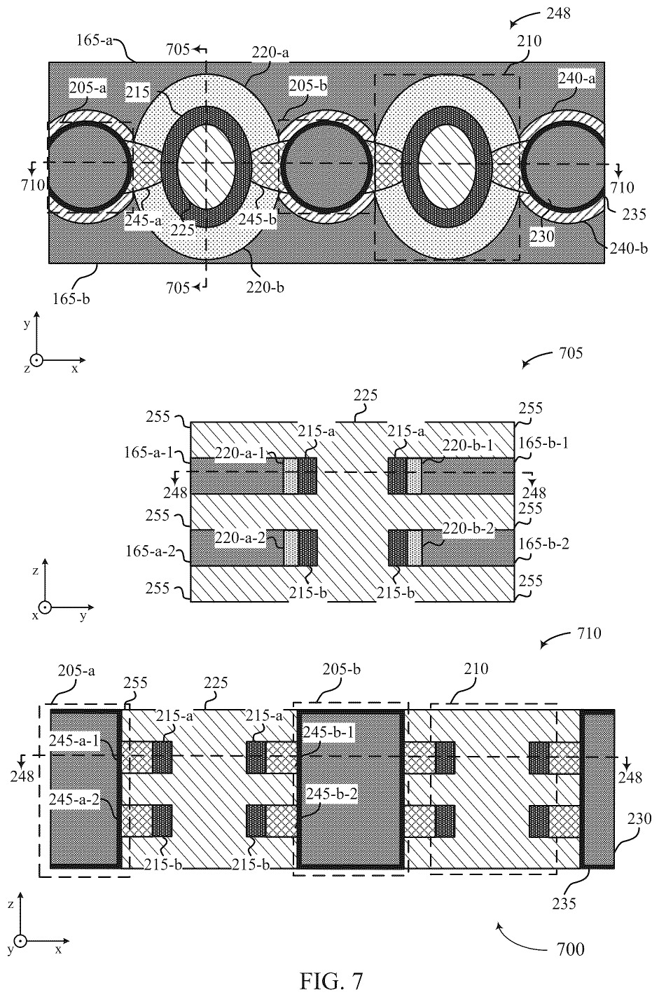

As described herein, each memory cell 220 may be formed using a charge trapping material (e.g., charge trapping multi-layer material), where, in some examples, the charge trapping material may be recessed (e.g., confined or positioned) at each word line deck (e.g., at a same even and odd word line 165), such that each memory cell 220-a may correspond to a respective word line 165-a and each memory cell 220-b may correspond to a respective word line 165-b. The aforementioned structure may be further described herein with reference to FIGS. 3 and 5A. Alternatively, in some examples, the charge trapping material may be continuous along the z direction of the memory device 200, which may be further described herein with reference to FIG. 6. Similarly, in some examples, the conductive layer 215 may be continuous (e.g., in the z direction) through the memory device 200. For example, as illustrated in the cross sectional view 250, the conductive layer 215 may be continuous (in the z direction) through the memory device 200. Alternatively, the conductive layer 215 may be recessed within each word line deck, which may be further described herein with reference to FIG. 7.

Each pillar 205 may include a metal material 230, which may be coupled with an inner surface of a barrier material 235 (e.g., titanium silicon (TiSi) or tungsten nitride (WN)). To avoid shorts between the metal material 230 of the pillars 205 and the word lines 165, the memory device 200 may include a dielectric material 240-a (e.g., aluminum oxide (AIOx), hafnium oxide (HfOx), silicon oxycarbide (SIOC), silicon carbonitride (SiCN), or a combination thereof) at a first end (in the y direction) of the pillar 205 that separates the first end of the pillar 205 from the word line 165-a. Similarly, the memory device may include a dielectric material 240-b at a second end of the pillar 205 that separates the pillar 205 from the word line 165-b. In such examples, respective portions of the dielectric material 240-a and 240-b may be recessed at each word line 165, which may be further described herein with reference to the cross sectional view 310 of FIG. 3. Alternatively, the dielectric materials 240 may extend continuously through the memory device 200 in the z direction.

Each pillar 205 may be coupled with the memory cells 220 and the conductive layer 215 of the piers 210 via respective conductive paths 245 (e.g., formed from n-type polysilicon). For example, with respect to the cross sectional view 250, the pillar 205-a may be coupled with each of the memory cells 220-a, each of the memory cells 220-b, and the conductive layer 215 via a respective conductive path 245-a, while the pillar 205-b may be coupled with each of the memory cells 220-a, each of the memory cells 220-b, and the conductive layer 215 via a respective conductive path 245-b. As described herein, a location of each respective conductive paths 245 may correspond to a respective word line 165 (e.g., a respective word line deck). For example, the locations of the conductive paths 245-a-1 and 245-b-1 may correspond to a first word line deck (e.g., first set of even and odd word lines 165), while the locations of the conductive paths 245-a-2 and 245-b-2 may correspond to a second word line deck (e.g., a second set of even and odd word lines). Techniques to manufacture the memory device 200 may be described herein with reference to FIGS. 5A through 5E.

The piers 210 and the pillars 205 may be formed in a two dimensional array. Accordingly, each column of pillars 205 may be coupled with a respective gate line (e.g., bit line 155), while each row pillars 205 may be coupled with a respective S/D line via a first transistor. The pillars 205 may be configured as source or drains to access the memory cells 220 of the piers 210. As described herein with reference to FIG. 1, each memory cell 220 may be configured to store two bits of data, where a first bit of data may be stored at a first end (in the x direction) of the memory cells 220 and a second bit of data may be stored at a second end (e.g., in the x direction) of the memory cells 220. Accordingly, depending on the S/D biases of the pillars 205, the two bits of the memory cells 220 may be independently programmed and read, resulting in reduced read latencies as compared to other devices (e.g., 3D NAND devices).

As an illustrative example, to access (e.g., read) a first bit of a memory cell 220-a, the gate line decoder (e.g., column decoder) may bias (e.g., turn on) the gate line coupled with the pillars 205-a and 205-b, while the gate line decoder deactivates (e.g., turns off) the other gate lines. As such, the S/D decoder may configure the pillar 205-a as a source by biasing the S/D line coupled with the pillar 205-a to a first voltage (e.g., 0V) and may configure the pillar 205-b as a drain by biasing the S/D line coupled with the pillar 205-b to a second voltage (e.g., 1V), where the first voltage is less than the second voltage. Accordingly, the S/D decoder may set the S/D lines coupled with the other S/D lines to a float state.

Based on biasing the gate line coupled with the pillars 205-a and 205-b and biasing the associated S/D lines, the row decoder (e.g., word line driver) may bias the word line 165 that corresponds to the target memory cell 220 to a third voltage (e.g., 5V) and bias the other word lines to ground, thereby accessing the first bit of the target memory cell 220. Alternatively, to access a second bit of the target memory cell 220, the S/D decoder may configure the pillar 205-b as a source by biasing the S/D line coupled with the pillar 205-b to a first voltage (e.g., 0V) and may configure the pillar 205-a as a drain by biasing the S/D line coupled with the pillar 205-a to a second voltage (e.g., 1V).

To write the first bit of the target memory cell, the gate line decoder (e.g., column decoder) may bias (e.g., turn on) the gate line coupled with the pillars 205-a and 205-b, while the gate line decoder deactivates (e.g., turns off) the other gate lines. As such, the S/D decoder may configure the pillar 205-a as the drain by biasing the S/D line coupled with the pillar 205-a to a first voltage (e.g., 5V) and may configure the pillar 205-b as a source by biasing the S/D line coupled with the pillar 205-b to a second voltage (e.g., 0V). Accordingly, the S/D decoder may set the S/D lines coupled with the other S/D lines to a float state. The word line decoder may bias the word line 165 that corresponds to the target memory cell 220 to a third voltage (e.g., 9V or relatively high voltage) and bias the other word lines to ground, thereby writing the first bit of the target memory cell 220.

Alternatively, to write the second bit of the target memory cell, the gate line decoder (e.g., column decoder) may bias (e.g., turn on) the gate line coupled with the pillars 205-a and 205-b, while the gate line decoder deactivates (e.g., turns off) the other gate lines. As such, the S/D decoder may configure the pillar 205-b as the drain by biasing the S/D line coupled with the pillar 205-b to a first voltage (e.g., 5V) and may configure the pillar 205-a as a source by biasing the S/D line coupled with the pillar 205-a to a second voltage (e.g., 0V). Accordingly, the S/D decoder may set the S/D lines coupled with the other S/D lines to a float state. The word line decoder may bias the word line 165 that corresponds to the target memory cell 220 to a third voltage (e.g., 9V) and bias the other word lines to ground, thereby writing the first bit of the target memory cell 220.

The memory cells 220 of the memory device 200 may be erased in blocks (e.g., sectors or groups) that include adjacent memory cells 220 associated with a same word line deck (e.g., same word line 165) across one or more piers 210. Accordingly, if a memory controller coupled with the memory device 200 verifies that all bits stored in the memory cells 220 of a block are in an erased state, the memory controller may reprogram each of the respective two bits of the memory cells 220 to a uniform state (e.g., each bit is set to ‘1’). Based on reprogramming the memory cells 220, the gate decoder may bias the gate lines associated with the block (e.g., groups of pillars and piers). The S/D decoder may bias each of the S/D lines associated with the sector to a first voltage (e.g., 5V) and the row decoder may bias a subset of the word lines 165 (e.g., both even and odd) associated with the block to a third voltage (e.g., −6V) and bias the remaining set of word lines 165 to ground. By doing so, each of the memory cells 220 within the identified sector may be erased. Techniques to read, write, and erase the memory cells 220 may be further described herein with reference to FIG. 4.

The memory device 200 may be configured to support code storage and execution for AI inference and applications. For example, the memory device 200 may include a relatively higher storage capacity (e.g., memory density) as compared to other memory systems (e.g., DRAM or 3D NAND systems), may include improved read performance (e.g., increased read speed, lower active power during read operations, lower cost per bit, lower standby power) as compared to other memory systems, may enable execute in place applications, among other benefits. Such characteristics may provide improved performance for systems operating AI applications.

FIG. 3 shows various cross sectional views 300 of the memory device 200 that supports 3D charge trapping NOR Flash memory architectures in accordance with examples as disclosed herein. As described herein with respect to FIG. 2, in some examples, the conductive layer 215 may extend continuously through the memory device 200 in the z direction. For example, with respect to the cross sectional view 305, the conductive layer 215 of each pier 210 may extend continuously through the stack of oxide layers 255 and word lines 165 of the memory device 200. Additionally, as described herein with respect to FIG. 2, each memory cell 220 may be positioned (e.g., recessed or confined) to a respective word line deck (e.g., set of even and odd word lines 165). With respect to the cross section view 305, each memory cell 220 may be positioned between respective oxide layers 255 and be coupled with a respective word line 165. For example, the memory cell 220-a-1 may be positioned between two oxide layers 255 and be coupled with the word line 165-a-1, while the memory cell 220-a-2 may be positioned between two oxide layers 255 and be coupled with the word line 165-a-2. Similarly, the memory cell 220-b-2 may be positioned between two oxide layers 255 and be coupled with the word line 165-b-1, while the memory cell 220-b-2 may be positioned between two oxide layers 255 and be coupled with the word line 165-b-2.

Further, as described herein with reference to FIG. 2, each respective dielectric material 240 may be positioned (e.g., recessed or confined) to a respective word line deck. That is, with respect to the cross sectional view 310, each dielectric material 240 may be positioned between oxide layers 255 and separate the word lines 165 from the pillars 205. As an illustrative example, the dielectric material 240-a-1 may be positioned between two oxide layers 255 (in the z direction) and be positioned between the word line 165-a-1 and the pillar 205 (in the y direction), while the dielectric material 240-a-2 may be positioned between two oxide layers 255 and be positioned between the word line 165-a-2. Similarly, the dielectric material 240-b-1 may be positioned between two oxide layers 255 (in the z direction) and be positioned between the word line 165-b-1 and the pillar 205 (in the y direction), while the dielectric material 240-b-2 may be positioned between two oxide layers 255 and be positioned between the word line 165-b-2. Techniques to manufacture the memory device 200 as illustrated in the cross sectional views 305 and 310 may be further described herein with reference to FIG. 5A through 5E.

FIG. 4 shows an example of a memory cell structure 400 that supports 3D charge trapping NOR Flash memory architectures in accordance with examples as disclosed herein. Aspects of the memory cell structure 400 may be implemented by aspects of the memory device 100 and the memory device 200, as described herein with reference to FIG. 1. For example, the memory cell structure 400 may be an example of the interconnections between the memory cells 220, the conductive layer 215, the pillars 205, and the word lines 165. The techniques described in the context of the memory cell structure 400 may describe the programming (e.g., writing), accessing (e.g., reading), and erasing of the memory cells 220.

For example, each memory cell 220 may include a stack of materials including a dielectric material 405-a (e.g., gate oxide including silicon oxide, silicon nitride, or a silicon oxide multi-layer), a dielectric material 405-b (e.g., tunnel oxide including silicon oxide, silicon nitride, or a silicon oxide multi-layer), and a charge trapping layer 410 (e.g., silicon nitride) positioned between the dielectric materials 405. Accordingly, the word line 165 (e.g., control gate) may be coupled with the dielectric material 405-a. Additionally, the pillar 205-a (e.g., configurable source or drain) may be coupled with the dielectric material 405-b via a respective conductive path 245-a, while the pillar 205-b (e.g., configurable drain or source) may be coupled with the dielectric material 405-b via a respective conductive path 245-b. Additionally, the conductive layer 215 may be coupled with each of the pillars 205 via the conductive paths and coupled with the dielectric material 405-b.

Each memory cell 220 may be configured to store two bits 415, where a bit 415-a may be stored at a first end of the charge trapping layer 410 (e.g., within a threshold distance of the pillar 205-a), while a bit 415-b may be stored at a second end of the charge trapping layer 410 (e.g., within a threshold distance of the pillar 205-b). Each bit 415 may be programmed according to a channel-hot electron procedure, where each side of the memory cell 220 may be programmed by swapping the source and drain biases of the pillars 205-a.

For example, to program the bit 415-b, the pillar 205-b may be configured as the drain and biased to a first voltage (e.g., 5V), while the pillar 205-a may be configured as the source and biased to a second voltage (e.g., 0V). The word line 165 associated with the memory cell 220 may be biased to a third voltage (e.g., 9V). By doing so, a current may flow from the pillar 205-a (e.g., the source) to the pillar 205-b (e.g., the drain) through the charge trapping layer 410, thereby trapping hot electrons into the trapping layer 410 and programming the bit 415-b.

Alternatively, to program the bit 415-a, the pillar 205-a may be configured as the drain and biased to a first voltage (e.g., 5V), while the pillar 205-b may be configured as the source and biased to a second voltage (e.g., 0V). The word line 165 associated with the memory cell 220 may be biased to a third voltage (e.g., 9V). By doing so, a current may flow from the pillar 205-b (e.g., the source) to the pillar 205-a (e.g., the drain), thereby creating hot electrons and trapping such hot electrons into the trapping layer 410 and programming the bit 415-a.

To read the bit 415-b, the pillar 205-a may be configured as the drain and biased to a first voltage (e.g., 1V), while the pillar 205-b may be configured as the source and biased to a second voltage (e.g., 0V or ground). The word line 165 associated with the memory cell 220 may be biased to a third voltage (e.g., 5V). By doing so, the sense component of the memory device 200 may sense the charge (e.g., bit 415-b) stored in the charge trapping layer 410. Alternatively, to read the bit 415-a, the pillar 205-b may be configured as the drain and biased to a first voltage (e.g., 1V), while the pillar 205-a may be configured as the source and biased to a second voltage (e.g., 0V or ground). The word line 165 associated with the memory cell 220 may be biased to a third voltage (e.g., 5V). By doing so, the sense component of the memory device 200 may sense the charge (e.g., bit 415-a) stored in the charge trapping layer 410.

The memory cell 220 of the memory device 200 may be erased in blocks (e.g., sectors or groups) that include adjacent memory cells 220 associated with a same word line deck (e.g., same word line 165) across one or more piers 210. That is, to protect against over- or under-erasure, all bits in a block are pre-programmed and then all S/D contacts (e.g., pillars 205) in the block are positively biased for erasing all the bits 415 in the block. Accordingly, each memory cell 220 within the block may be erased via a through hole injection generated by the junction between the conductive paths 245 (e.g., n-type polysilicon) and the conductive layer 215 (e.g., p-type polysilicon). For example, a memory controller coupled with the memory device 200 may verify that all bits 415 stored in the memory cell 220 are in an erased state (e.g., store a logic value of ‘0’), the memory controller may reprogram each of the respective two bits of the memory cells 220 to a uniform state (e.g., each bit is set to ‘1’). Based on reprogramming the bits 415 to a logical ‘1’, the pillars 205-a and 205-b may be biased to a first voltage (e.g., 5V) and the word line 165 may be biased to a third voltage (e.g., −6V). By doing so, the bits 415 of the memory cell may be erased.

FIG. 5A shows an example of a processing step 501 that supports 3D charge trapping NOR Flash memory architectures in accordance with examples as disclosed herein. Aspects of the processing step 501 may be implemented to manufacture the memory device 100 and the memory device 200 as described herein with reference to FIGS. 1 and 2. The techniques described in the context of the processing step 501 may be used to form each of the piers 210. FIG. 5A may illustrate various view of the memory device during the processing step 501, such as a top view 506, a top view 508, and a cross-sectional view 510, where the top view 506 may illustrate a view of a nitride layer 505, the top view 508 may illustrate a view of the oxide layer 255, and the cross-sectional view 510 may illustrate the stack of layers 502 including the piers 210.

For example, a stack of layers 502 including alternating nitride layers 505 and oxide layers 255 may be formed over a substrate. Based on forming the stack of layers 502, multiple pier cavities, one for each pier 210, may be etched through the nitride layers 505 and the oxide layers 255 to the substrate, thereby forming a comb-like structure, as illustrated in FIG. 2. Based etching the multiple pier cavities, a dielectric material may be formed in each pair cavity. Accordingly, a subset of the pier cavities (e.g., active piers) chosen to include memory cells 220 may be exposed to dielectric exhume and experience the following cell integration process, while the remaining subset of pier cavities may remain protected and not exhumed by a mask. In such examples, the pier cavities may be formed in an elliptical shape, as illustrated in FIG. 5A. In some other examples, the pier cavities may be formed in a circular shape, a square shape, a rectangular shape, a rounded rectangular shape, or any combination thereof.

In some examples, based on forming the pier cavities (e.g., exhuming the subset of pier cavities), a nitride recess procedure may be performed through each pier cavity to remove a respective portion of nitride from each nitride layer 505 to form multiple voids. For example, with respect to the cross sectional view 510, a respective portion of the nitride layers 505-a and 505-b may be removed via the nitride recess procedure. In such examples, based on forming the pier cavities and voids in the nitride layers 505, memory cell material (e.g., charge trapping multi-stack, an oxide, nitride, oxide layer, as described herein with reference to FIG. 4) may be formed within each pier cavity and the voids in the nitride layers 505. Based on forming the memory cell material, an etching procedure may be performed to remove a portion of the memory cell material to re-expose the pier cavities. By doing so, the memory cells 220 may be formed within the voids of the nitride layers 505 and be positioned (e.g., recessed or confined) between each oxide layer 255 and coupled with each nitride layer 505. For example, with respect to the cross sectional view 510, a memory cell 220-1 may be formed at the nitride layer 505-a and the nitride layer 505-b, while a memory cell 220-2 may be formed at the nitride layers 505-a and 505-b based on performing the nitride recess and etching procedure, thereby positioning each memory cell 220 at a respective nitride layer 505. In some examples, the nitride recess procedure may be skipped, in favor a continuous memory cell material through the stack of layers 502, which may be further described and illustrated herein with respect to FIG. 6.

Based on removing the portion of the memory cell material to re-expose the pier cavities, a conductive material (e.g., p-type polysilicon material) may be deposited into each pier cavity. In response to depositing the conductive material, an etching procedure may be performed to remove a portion of the conductive material to form multiple core cavities. By removing the portion of the conductive material, the conductive layer 215 in each pier 210 may be formed, where the conductive layer 215 may be coupled with an inner surface of each memory cell 220. Based on forming the core cavities, the core dielectric material 225 may be deposited in each of the core cavities, thereby forming each pier 210.

FIG. 5B shows an example of a processing step 503 that supports 3D charge trapping NOR Flash memory architectures in accordance with examples as disclosed herein. Aspects of the processing step 503 may be implemented to manufacture the memory device 100 and the memory device 200 as described herein with reference to FIGS. 1 and 2. The techniques described in the context of the processing step 503 may be performed in response to the processing step 501 and may be used in the formation of each pillar 205 and word lines 165. FIG. 5B may illustrate various view of the memory device during the processing step 503, such as a top view 516, a top view 518, and a cross-sectional view 520, where the top view 516 may illustrate a view of a word line 165 (e.g., a metal layer), the top view 518 may illustrate a view of the oxide layer 255, and the cross-sectional view 520 may illustrate the stack of layers 502.

For example, based on forming the piers 210, multiple cavities 515 (e.g., pairs of cavities) may be formed in the stack of layers 502. In such examples, each cavity 515 may be formed adjacent to the piers 210, such that each pier 210 may be positioned between each cavity 515. Based on forming each cavity 515, a metallization procedure may be performed to replace the nitride layers 505 with a metal material (e.g., metal material 230), thereby forming the word lines 165, as viewed in the cross sectional view 520. In some examples, the metallization procedure may be performed prior to forming the cavities 515. In some other examples, the metallization procedure may be performed in response to forming the cavities 515, where in such examples, the metallization procedure may be performed through the cavities 515.

FIG. 5C shows an example of a processing step 507 that supports 3D charge trapping NOR Flash memory architectures in accordance with examples as disclosed herein. Aspects of the processing step 507 may be implemented to manufacture the memory device 100 and the memory device 200 as described herein with reference to FIGS. 1 and 2. The techniques described in the context of the processing step 507 may be performed in response to the processing step 503 and may be used in the formation of the dielectric material 240 for each pillar 205. FIG. 5C may illustrate various view of the memory device during the processing step 507, such as a top view 522, a top view 524, and a cross-sectional view 525, where the top view 522 may illustrate a view of a word line 165 (e.g., a metal layer), the top view 524 may illustrate a view of the oxide layer 255, and the cross-sectional view 525 may illustrate the stack of layers 502.

For example, a metal recession procedure may be performed to remove a respective portion of metal from each word line 165, thereby forming multiple voids within each word line 165. That is, with respect to the cross sectional view 525, a portion of the word lines 165-a-1, 165-a-2, 165-b-1, and 165-b-2 may be removed according to the metal recession procedure, where such a metal recession procedure may be performed through each cavity 515.

In response to performing the metal reception procedure, the dielectric material 240 may be deposited into the cavities 515 and into the voids formed by the metal recession procedure, such that the dielectric material 240 may be coupled with (e.g., touching) the word lines 165. Based on depositing the dielectric material 240 into the cavities 515, a selecting etching procedure (e.g., selective etch back) may be performed to remove the dielectric material 240 from the cavities 515 and from a portion of each of the word line decks, thereby forming the dielectric materials 240-a and 240-b. For example, in response to the etching procedure, each word line 165 may be separated from the cavities 515 by a respective dielectric material 240.

That is, with respect to the cross sectional view 525, the dielectric material 240-a-1 may be positioned between the oxide layers 255 (e.g., confined within a single word line deck) and separate the word line 165-a-1 from the cavity 515. Similarly, the dielectric material 240-a-2 may be positioned between the oxide layers 255 (e.g., confined within a single word line deck) and separate the word line 165-a-2 from the cavity 515. Further, the dielectric material 240-b-1 may be positioned between the oxide layers 255 (e.g., confined within a single word line deck) and separate the word line 165-b-1 from the cavity 515, while the dielectric material 240-b-2 may be positioned between the oxide layers 255 (e.g., confined within a single word line deck) and separate the word line 165-b-2 from the cavity 515.

FIG. 5D shows an example of a processing step 509 that supports 3D charge trapping NOR Flash memory architectures in accordance with examples as disclosed herein. Aspects of the processing step 509 may be implemented to manufacture the memory device 100 and the memory device 200 as described herein with reference to FIGS. 1 and 2. The techniques described in the context of the processing step 509 may be performed in response to the processing step 507 and may be used in the formation of the conductive paths 245. FIG. 5D may illustrate various view of the memory device during the processing step 509, such as a top view 526, a top view 528, and a cross-sectional view 530, where the top view 526 may illustrate a view of a word line 165 and conductive path 245, the top view 528 may illustrate a view of the oxide layer 255, and the cross-sectional view 525 may illustrate the stack of layers 502.

In response to forming the dielectric materials 240, an etching procedure may be performed to remove a portion of the memory cells 220 at each side of the pier 210, thereby separating the memory cells into the memory cells 220-a and the memory cells 220-b. For example, at each word line deck (e.g., each word line 165 level within the stack of layers), a selective etching procedure may be performed to form multiple voids that extend from the cavities 515 through the memory cells 220 to the conductive layer 215. Based on forming the multiple cavities, each corresponding to a respective word line deck, a conductive material (e.g., n-type poly-silicon material) may be deposited into the cavities 515 and into the multiple voids formed by the previous etching procedure. Based on depositing the conductive material, an etching procedure may be performed to remove a portion of the conductive material, thereby re-exposing the cavities 515 and forming the conductive paths 245.

For example, with respect to the cross sectional view 530, in response to performing the processing step 509, each of the conductive paths 245 may be formed, where each conductive path may be positioned between each oxide layer 255 and correspond to a respective word line deck. As an illustrative example, a position (e.g., in the z direction of the stack) of the conductive paths 245-a-1 and 245-b-1 may be correspond to a position of the word lines 165-a-1 and 165-b-1, respectively, while a position (e.g., in the z direction of the stack) of the conductive paths 245-a-2 and 245-b-2 may be correspond to a position of the word lines 165-a-2 and 165-b-2, respectively.

As such, each conductive path 245 may be coupled with the conductive layer 215, where the junction between the conductive layer 215 (e.g., p-type poly-silicon) and the conductive paths 245 (e.g., n-type polysilicon) may be used for erasing the memory cells 220 (e.g., used for the band-to-band hot hole creation used by the erasing mechanism), as described herein with reference to FIGS. 2 and 4. Additionally, each conductive path 245 may be coupled with a respective memory cell 220-a and be coupled with a respective memory cell 220-b.

FIG. 5E shows an example of a processing step 511 that supports 3D charge trapping NOR Flash memory architectures in accordance with examples as disclosed herein. Aspects of the processing step 511 may be implemented to manufacture the memory device 100 and the memory device 200 as described herein with reference to FIGS. 1 and 2. The techniques described in the context of the processing step 511 may be performed in response to the processing step 509 and may be used in the formation of the pillars 205. FIG. 5E may illustrate various view of the memory device during the processing step 511, such as a top view 248, a top view 534, and a cross-sectional view 530, where the top view 248 may illustrate a view of a word line 165 and conductive path 245, the top view 534 may illustrate a view of the oxide layer 255, and the cross-sectional view 535 may illustrate the stack of layers 502.

That is, in response to forming each of the conductive paths 245, the barrier material 235 may be deposited into each cavity 515. Based on depositing the barrier material 235, an etching procedure may be performed to remove a portion of the barrier material 235, thereby forming multiple cavities. Alternatively, the barrier material 235 may be selectively deposited onto the sidewalls of the cavities 515. Accordingly, based on depositing the barrier material 235, the metal material 230 may be deposited into the cavities, thereby forming the pillars 205, which may be viewed in the z direction from the cross sectional view 535.

FIG. 6 shows an example of a memory device 600 that supports 3D charge trapping NOR Flash memory architectures in accordance with examples as disclosed herein. Aspects of the memory device 600 may be implemented by the memory device 100 and the memory device 200, as described herein with reference to FIGS. 1 and 2. Similarly, aspects of the memory device 600 may be formed according to the techniques described herein with reference to FIGS. 5A through 5E. The memory device 600 may be an example of memory device 200 that includes a continuous charge trapping material (e.g., continuous memory cell material) through the stack of oxide layers 255 and word lines 165.

For example, with respect to the cross sectional views 605 and 610, the charge trapping material (as described herein with reference to FIG. 4) that forms the memory cells 220-a may be continuous through the z direction of the memory device 600. Similarly, the charge trapping material that forms the memory cells 220-b may be continuous through the z direction of the memory device 600. In such examples, although the charge trapping material may be continuous throughout the memory device 600, the memory cells 220 (e.g., points of charge trapping material that store the data) may be formed at the intersection of the word lines 165 and the charge trapping material.

For example, the memory cell 220-a-1 may be formed at the intersection of the word line 165-a-1 and the charge trapping material that forms the memory cells 220-a, while the memory cell 220-a-2 may be formed at the intersection of the word line 165-a-2 and the charge trapping material that forms the memory cells 220-a. Similarly, the memory cell 220-b-1 may be formed at the intersection of the word line 165-b-1 and the charge trapping material that forms the memory cells 220-b, while the memory cell 220-b-2 may be formed at the intersection of the word line 165-b-2 and the charge trapping material that forms the memory cells 220-b.

To achieve the structure of the memory device 600, one or more of the processing steps described in FIGS. 5A through 5E may be skipped. For example, to achieve the continuous charge trapping material through the memory device, in response to depositing the charge trapping material into each of the pier cavities, as described herein with reference to FIG. 5A, the nitride recess procedure, the etch back procedure, or both may be skipped. Accordingly, in such examples, the charge trapping material may be deposited onto the sidewalls of each of the pier cavities. In response to such deposition, the conductive layer 215 may be deposited into a remaining portion of the pier cavities, thereby forming the continuous charge trapping material through the memory device 600.

In such examples, the manufacture of the memory device 600 may be simplified relative to the manufacture of the memory device 200 (e.g., with memory cells 220-a recessed at each word line deck) by removing the nitride recess and etch back procedures. However, the resulting memory cells 220 may have a relatively lower immunity to disturbs and relatively lower data retention than the memory cells of the memory device 200 due to the trapped charge lateral migration through the continuous charge trapping material.

FIG. 7 shows an example of memory device 700 that supports 3D charge trapping NOR Flash memory architectures in accordance with examples as disclosed herein. Aspects of the memory device 700 may be implemented by the memory device 100 and the memory device 200, as described herein with reference to FIGS. 1 and 2. Similarly, aspects of the memory device 700 may be formed according to the techniques described herein with reference to FIGS. 5A through 5E. The memory device 700 may be an example of memory device 200, where the conductive layer 215 may be positioned (e.g., recessed or confined) at each word line deck.

For example, with respect to the cross sectional view 705, the conductive layer 215-a (e.g., a first conductive layer) may be positioned between two oxide layers 255 and be coupled with the memory cells 220-a-1 and 220-b-1, thereby being recessed at a first word line deck (e.g., the word line deck or layer corresponding to word lines 165-a-1 and 165-b-1). Similarly, the conductive layer 215-b (e.g., a second conductive layer) may be positioned between two oxide layers 255 and be coupled with the memory cells 220-a-2 and 220-b-2, thereby being recessed at a second word line deck (e.g., the word line deck or layer corresponding to the word lines 165-a-2 and 165-b-2).

Additionally, with respect to the cross sectional view 710, the conductive layers 215 may be coupled with a respective conductive path 245. For example, due to each conductive layer 215 being recessed at a respective word line deck, the conductive layer 215-a may be coupled with the conductive paths 245-a-1 and 245-b-1, while the conductive layer 215-b may be coupled with the conductive paths 245-a-2 and 245-b-2. The structure illustrated in the memory device 700 may enable the memory cells 220 to be fully confined (e.g., recessed or positioned) at each word line deck.

To achieve the structure of the memory device 600, one or more of the processing steps may be added. For example, to achieve the continuous charge trapping material through the memory device, in response to depositing the charge trapping layer into the pier cavities, as described herein with reference to FIG. 5A, multiple deposition and recess procedures may be performed to form the conductive layers 215 at each respective word line deck.

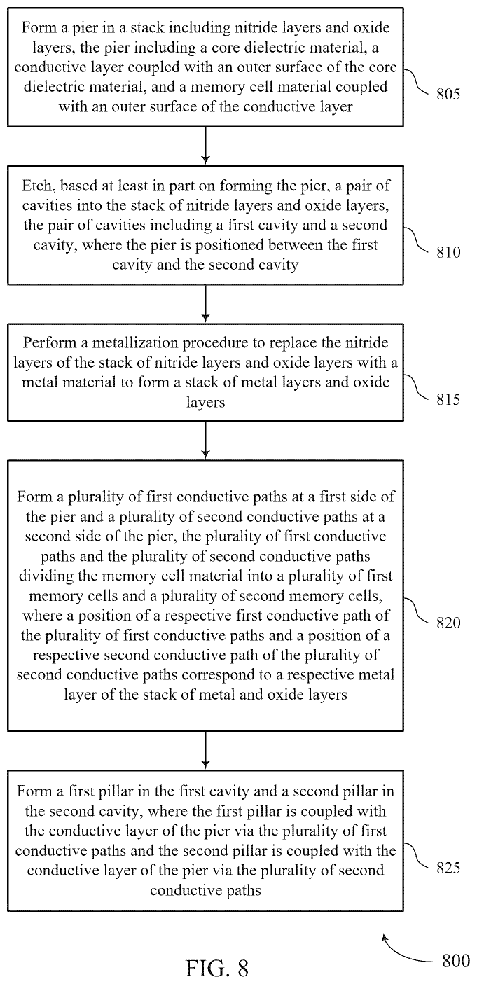

FIG. 8 shows a flowchart illustrating a method 800 that supports 3D charge trapping NOR Flash memory architectures in accordance with examples as disclosed herein. The operations of method 800 may be implemented by a manufacturing system or its components as described herein. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include forming a pier in a stack including nitride layers and oxide layers, the pier including a core dielectric material, a conductive layer coupled with an outer surface of the core dielectric material, and a memory cell material coupled with an outer surface of the conductive layer.

At 810, the method may include etching, based at least in part on forming the pier, a pair of cavities into the stack of nitride layers and oxide layers, the pair of cavities including a first cavity and a second cavity, where the pier is positioned between the first cavity and the second cavity.

At 815, the method may include performing a metallization procedure to replace the nitride layers of the stack of nitride layers and oxide layers with a metal material to form a stack of metal layers and oxide layers.

At 820, the method may include forming a plurality of first conductive paths at a first side of the pier and a plurality of second conductive paths at a second side of the pier, the plurality of first conductive paths and the plurality of second conductive paths dividing the memory cell material into a plurality of first memory cells and a plurality of second memory cells, where a position of a respective first conductive path of the plurality of first conductive paths and a position of a respective second conductive path of the plurality of second conductive paths correspond to a respective metal layer of the stack of metal and oxide layers.

At 825, the method may include forming a first pillar in the first cavity and a second pillar in the second cavity, where the first pillar is coupled with the conductive layer of the pier via the plurality of first conductive paths and the second pillar is coupled with the conductive layer of the pier via the plurality of second conductive paths.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a pier in a stack including nitride layers and oxide layers, the pier including a core dielectric material, a conductive layer coupled with an outer surface of the core dielectric material, and a memory cell material coupled with an outer surface of the conductive layer; etching, based at least in part on forming the pier, a pair of cavities into the stack of nitride layers and oxide layers, the pair of cavities including a first cavity and a second cavity, where the pier is positioned between the first cavity and the second cavity; performing a metallization procedure to replace the nitride layers of the stack of nitride layers and oxide layers with a metal material to form a stack of metal layers and oxide layers; forming a plurality of first conductive paths at a first side of the pier and a plurality of second conductive paths at a second side of the pier, the plurality of first conductive paths and the plurality of second conductive paths dividing the memory cell material into a plurality of first memory cells and a plurality of second memory cells, where a position of a respective first conductive path of the plurality of first conductive paths and a position of a respective second conductive path of the plurality of second conductive paths correspond to a respective metal layer of the stack of metal and oxide layers; and forming a first pillar in the first cavity and a second pillar in the second cavity, where the first pillar is coupled with the conductive layer of the pier via the plurality of first conductive paths and the second pillar is coupled with the conductive layer of the pier via the plurality of second conductive paths.
Aspect 2: The method, apparatus, or non-transitory computer-readable medium of aspect 1, further including operations, features, circuitry, logic, means, or instructions, or any combination thereof for performing, based at least in part on etching the pair of cavities and performing the metallization procedure, a metal recession procedure to remove a respective portion of metal from each metal layer of the stack of metal and oxide layers to form a plurality of voids and depositing, in each void of the plurality of voids, a dielectric material, where forming the first pillar and the second pillar is based at least in part on depositing the dielectric material.
Aspect 3: The method, apparatus, or non-transitory computer-readable medium of any of aspects 1 through 2, where forming the first pillar and the second pillar includes operations, features, circuitry, logic, means, or instructions, or any combination thereof for depositing a first barrier material into the first cavity and a second barrier material into the second cavity; etching a third cavity into the first barrier material and a fourth cavity into the second barrier material; and depositing a second metal material into the third cavity and into the fourth cavity.
Aspect 4: The method, apparatus, or non-transitory computer-readable medium of any of aspects 1 through 3, where forming the plurality of first conductive paths includes operations, features, circuitry, logic, means, or instructions, or any combination thereof for etching a plurality of third voids through the memory cell material to the conductive layer at the first side of the pier, a position of each third void of the plurality of third voids corresponding to the respective metal layer of the stack of metal and oxide layers; depositing, into the first cavity and into each third void of the plurality of third voids, a conductive material; and etching the conductive material from the first cavity to form the plurality of first conductive paths.
Aspect 5: The method, apparatus, or non-transitory computer-readable medium of any of aspects 1 through 4, where forming the plurality of second conductive paths includes operations, features, circuitry, logic, means, or instructions, or any combination thereof for etching a plurality of third voids through the memory cell material to the conductive layer at the second side of the pier, a position of each third void of the plurality of third voids corresponding to the respective metal layer of the stack of metal and oxide layers; depositing, into the second cavity and into each third void of the plurality of third voids, a conductive material; and etching the conductive material from the second cavity to form the plurality of second conductive paths.
Aspect 6: The method, apparatus, or non-transitory computer-readable medium of any of aspects 1 through 5, where forming the pier includes operations, features, circuitry, logic, means, or instructions, or any combination thereof for etching a third cavity into the stack of nitride and oxide layers; forming the memory cell material in the third cavity; etching a fourth cavity into the memory cell material; forming the conductive layer into the fourth cavity; etching a fifth cavity into the conductive layer; and depositing the core dielectric material into the fifth cavity.
Aspect 7: The method, apparatus, or non-transitory computer-readable medium of aspect 6, further including operations, features, circuitry, logic, means, or instructions, or any combination thereof for performing, based at least in part on etching the third cavity, a nitride recess procedure to remove a respective portion of nitride from each nitride layer of the stack of nitride and oxide layers to form a plurality of voids in each nitride layer, where the memory cell material is formed within each void of the plurality of voids.
Aspect 8: The method, apparatus, or non-transitory computer-readable medium of any of aspects 1 through 7, where the plurality of first memory cells are positioned at a third side of the pier and the plurality of second memory cells are positioned at a fourth side of the pier.
Aspect 9: The method, apparatus, or non-transitory computer-readable medium of any of aspects 1 through 8, where the plurality of first memory cells and the plurality of second memory cells each include a first dielectric material, a second dielectric material, and a charge trapping layer between the first dielectric material and the second dielectric material.
Aspect 10: The method, apparatus, or non-transitory computer-readable medium of aspect 9, where each first memory cell of the plurality of first memory cells is configured to store a first bit at a first end of the charge trapping layer based at least in part on trapping a first electron at the first end of the charge trapping layer and each first memory cell of the plurality of first memory cells is configured to store a second bit at a second end of the charge trapping layer based at least in part on trapping a second electron at the second end of the charge trapping layer.
Aspect 11: The method, apparatus, or non-transitory computer-readable medium of any of aspects 9 through 10, where each second memory cell of the plurality of second memory cells is configured to store a first bit at a first end of the charge trapping layer based at least in part on trapping a first electron at the first end of the charge trapping layer and each second memory cell of the plurality of second memory cells is configured to store a second bit at a second end of the charge trapping layer based at least in part on trapping a second electron at the second end of the charge trapping layer.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 12: A memory device, including: a pair of pillars including a first pillar and a second pillar; a pier positioned between the first pillar and the second pillar, the pier including a conductive layer, a plurality of first memory cells coupled with a first portion of the conductive layer at a first end of the pier and a plurality of second memory cells coupled with a second portion of the conductive layer at a second end of the pier; a plurality of pairs of conductive paths each including a first conductive path coupling the conductive layer with the first pillar and a second conductive path coupling the conductive layer with the second pillar, where each first conductive path couples a respective first memory cell of the plurality of first memory cells and a respective second memory cell of the plurality of second memory cells with the first pillar, and where each second conductive path couples the respective first memory cell of the plurality of first memory cells and the respective second memory cell of the plurality of second memory cells with the second pillar; a plurality of first word lines configured to couple with each first memory cell of the plurality of first memory cells of the pier; and a plurality of second word lines configured to couple with each second memory cell of the plurality of second memory cells of the pier.
Aspect 13: The memory device of aspect 12, further including: a first access line coupled with the first pillar, the first access line extending along a first direction; a second access line coupled with the second pillar and configured to bias the second pillar, the second access line extending along the first direction; and a gate line coupled with the first pillar and the second pillar, the gate line extending along a second direction perpendicular to the first direction.
Aspect 14: The memory device of aspect 13, where: the first pillar is configured as a source for accessing a respective first memory cell of the plurality of first memory cells or a respective second memory cell of the plurality of second memory cells based at least in part on the first access line biasing the first pillar to a first voltage, and the second pillar is configured as a drain for accessing the respective first memory cell of the plurality of first memory cells or the respective second memory cell of the plurality of second memory cells based at least in part on the second access line biasing the second pillar to a second voltage, the second voltage being greater than the first voltage.
Aspect 15: The memory device of any of aspects 13 through 14, where: the first pillar is configured as a drain for accessing a respective first memory cell of the plurality of first memory cells or a respective second memory cell of the plurality of second memory cells based at least in part on the first access line biasing the first pillar to a first voltage, and the second pillar is configured as a source for accessing the respective first memory cell of the plurality of first memory cells or the respective second memory cell of the plurality of second memory cells based at least in part on the second access line biasing the second pillar to a second voltage, the second voltage being less than the first voltage.
Aspect 16: The memory device of any of aspects 13 through 15, where the first pillar is coupled with the gate line and the first access line via a first transistor and the second pillar is coupled with the gate line the second access line via a second transistor.
Aspect 17: The memory device of any of aspects 12 through 16, further including: a plurality of pairs of pillars including the pair of pillars; and a plurality of piers including the pier, where each pier of the plurality of piers is positioned between a respective pair of pillars of the plurality of pairs of pillars and each pier of the plurality of piers includes a respective conductive layer, a respective plurality of first memory cells, and a respective plurality of second memory cells.
Aspect 18: The memory device of any of aspects 12 through 17, where the pier includes a core dielectric material coupled with an inner surface of the conductive layer.
Aspect 19: The memory device of any of aspects 12 through 18, where: the first pillar includes a first core metal material, a first portion of a first dielectric material separating the first core metal material from each first word line of the plurality of first word lines, a second portion of the first dielectric material separating the first core metal material from each second word line of the plurality of second word lines, and the second pillar includes a second core metal material, a third portion of the first dielectric material separating the second core metal material from each first word line of the plurality of first word lines, a fourth portion of the first dielectric material separating the second core metal material from each second word line of the plurality of second word lines.
Aspect 20: The memory device of any of aspects 12 through 19, where the conductive layer includes a p-type polysilicon material, and the first conductive path and the second conductive path of each pair of conductive layers of the plurality of pairs of conductive paths includes an n-type polysilicon material.
Aspect 21: The memory device of any of aspects 12 through 20, where the plurality of first memory cells and the plurality of second memory cells each include a first dielectric material, a second dielectric material, and a charge trapping layer between the first dielectric material and the second dielectric material.
Aspect 22: The memory device of aspect 21, where: each first memory cell of the plurality of first memory cells is configured to store a first bit at a first end of the charge trapping layer based at least in part on trapping a electrons at the first end of the charge trapping layer, and each first memory cell of the plurality of first memory cells is configured to store a second bit at a second end of the charge trapping layer based at least in part on trapping electrons at the second end of the charge trapping layer.
Aspect 23: The memory device of any of aspects 21 through 22, where: each second memory cell of the plurality of second memory cells is configured to store a first bit at a first end of the charge trapping layer based at least in part on trapping electrons at the first end of the charge trapping layer, and each second memory cell of the plurality of second memory cells is configured to store a second bit at a second end of the charge trapping layer based at least in part on trapping electrons at the second end of the charge trapping layer.
Aspect 24: The memory device of any of aspects 21 through 23, where a respective first memory cell of the plurality of first memory cells and a respective second memory cell of the plurality of second memory cells are erased based at least in part on biasing the first pillar and the second pillar up to a first threshold voltage, biasing a first word line of the plurality of first word lines and a second word line of the plurality of second word lines to a second voltage, the first word line corresponding to a same position as the respective first memory cell and the second word line corresponding to a same position as the respective second memory cell.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a pair of pillars comprising a first pillar and a second pillar;
a pier positioned between the first pillar and the second pillar, the pier comprising a conductive layer, a plurality of first memory cells coupled with a first portion of the conductive layer at a first end of the pier and a plurality of second memory cells coupled with a second portion of the conductive layer at a second end of the pier;
a plurality of pairs of conductive paths each comprising a first conductive path coupling the conductive layer with the first pillar and a second conductive path coupling the conductive layer with the second pillar, wherein each first conductive path couples a respective first memory cell of the plurality of first memory cells and a respective second memory cell of the plurality of second memory cells with the first pillar, and wherein each second conductive path couples the respective first memory cell of the plurality of first memory cells and the respective second memory cell of the plurality of second memory cells with the second pillar;
a plurality of first word lines configured to couple with each first memory cell of the plurality of first memory cells of the pier; and
a plurality of second word lines configured to couple with each second memory cell of the plurality of second memory cells of the pier.

2. The memory device of claim 1, further comprising:
a first access line coupled with the first pillar, the first access line extending along a first direction;
a second access line coupled with the second pillar and configured to bias the second pillar, the second access line extending along the first direction; and
a gate line coupled with the first pillar and the second pillar, the gate line extending along a second direction perpendicular to the first direction.

3. The memory device of claim 2, wherein:
the first pillar is configured as a source for accessing a first memory cell of the plurality of first memory cells or a second memory cell of the plurality of second memory cells based at least in part on the first access line biasing the first pillar to a first voltage, and
the second pillar is configured as a drain for accessing the first memory cell of the plurality of first memory cells or the second memory cell of the plurality of second memory cells based at least in part on the second access line biasing the second pillar to a second voltage, the second voltage being greater than the first voltage.

4. The memory device of claim 2, wherein:
the first pillar is configured as a drain for accessing a first memory cell of the plurality of first memory cells or a second memory cell of the plurality of second memory cells based at least in part on the first access line biasing the first pillar to a first voltage, and
the second pillar is configured as a source for accessing the first memory cell of the plurality of first memory cells or the second memory cell of the plurality of second memory cells based at least in part on the second access line biasing the second pillar to a second voltage, the second voltage being less than the first voltage.

5. The memory device of claim 2, wherein the first pillar is coupled with the gate line and the first access line via a first transistor and the second pillar is coupled with the gate line the second access line via a second transistor.

6. The memory device of claim 1, further comprising:
a plurality of pairs of pillars comprising the pair of pillars; and
a plurality of piers comprising the pier, wherein each pier of the plurality of piers is positioned between a respective pair of pillars of the plurality of pairs of pillars and each pier of the plurality of piers comprises a respective conductive layer, a respective plurality of first memory cells, and a respective plurality of second memory cells.

7. The memory device of claim 1, wherein the pier comprises a core dielectric material coupled with an inner surface of the conductive layer.

8. The memory device of claim 1, wherein:
the first pillar comprises a first core metal material, a first portion of a first dielectric material separating the first core metal material from each first word line of the plurality of first word lines, a second portion of the first dielectric material separating the first core metal material from each second word line of the plurality of second word lines, and
the second pillar comprises a second core metal material, a third portion of the first dielectric material separating the second core metal material from each first word line of the plurality of first word lines, a fourth portion of the first dielectric material separating the second core metal material from each second word line of the plurality of second word lines.

9. The memory device of claim 1, wherein the conductive layer comprises a p-type polysilicon material, and the first conductive path and the second conductive path of each pair of conductive layers of the plurality of pairs of conductive paths comprises an n-type polysilicon material.

10. The memory device of claim 1, wherein the plurality of first memory cells and the plurality of second memory cells each comprise a first dielectric material, a second dielectric material, and a charge trapping layer between the first dielectric material and the second dielectric material.

11. The memory device of claim 10, wherein:
each first memory cell of the plurality of first memory cells is configured to store a first bit at a first end of the charge trapping layer based at least in part on trapping a first electron at the first end of the charge trapping layer, and
each first memory cell of the plurality of first memory cells is configured to store a second bit at a second end of the charge trapping layer based at least in part on trapping a second electron at the second end of the charge trapping layer.

12. The memory device of claim 10, wherein:
each second memory cell of the plurality of second memory cells is configured to store a first bit at a first end of the charge trapping layer based at least in part on trapping electrons at the first end of the charge trapping layer, and
each second memory cell of the plurality of second memory cells is configured to store a second bit at a second end of the charge trapping layer based at least in part on trapping electrons at the second end of the charge trapping layer.

13. The memory device of claim 10, wherein a first memory cell of the plurality of first memory cells and a second memory cell of the plurality of second memory cells are erased based at least in part on biasing the first pillar and the second pillar up to a first threshold voltage, biasing a first word line of the plurality of first word lines and a second word line of the plurality of second word lines to a second voltage, the first word line corresponding to a same position as the first memory cell and the second word line corresponding to a same position as the second memory cell.

14. A method for manufacturing a memory device, comprising:
forming a pier in a stack comprising nitride layers and oxide layers, the pier comprising a core dielectric material, a conductive layer coupled with an outer surface of the core dielectric material, and a memory cell material coupled with an outer surface of the conductive layer;
etching, based at least in part on forming the pier, a pair of cavities into the stack of nitride layers and oxide layers, the pair of cavities comprising a first cavity and a second cavity, wherein the pier is positioned between the first cavity and the second cavity;
performing a metallization procedure to replace the nitride layers of the stack of nitride layers and oxide layers with a metal material to form a stack of metal layers and oxide layers;
forming a plurality of first conductive paths at a first side of the pier and a plurality of second conductive paths at a second side of the pier, the plurality of first conductive paths and the plurality of second conductive paths dividing the memory cell material into a plurality of first memory cells and a plurality of second memory cells, wherein a position of a respective first conductive path of the plurality of first conductive paths and a position of a respective second conductive path of the plurality of second conductive paths correspond to a respective metal layer of the stack of metal and oxide layers; and
forming a first pillar in the first cavity and a second pillar in the second cavity, wherein the first pillar is coupled with the conductive layer of the pier via the plurality of first conductive paths and the second pillar is coupled with the conductive layer of the pier via the plurality of second conductive paths.

15. The method of claim 14, further comprising:
performing, based at least in part on etching the pair of cavities and performing the metallization procedure, a metal recession procedure to remove a respective portion of metal from each metal layer of the stack of metal and oxide layers to form a plurality of voids; and
depositing, in each void of the plurality of voids, a dielectric material, wherein forming the first pillar and the second pillar is based at least in part on depositing the dielectric material.

16. The method of claim 14, wherein forming the first pillar and the second pillar comprises:
depositing a first barrier material into the first cavity and a second barrier material into the second cavity;
etching a third cavity into the first barrier material and a fourth cavity into the second barrier material; and
depositing a second metal material into the third cavity and into the fourth cavity.

17. The method of claim 14, wherein forming the plurality of first conductive paths comprises:
etching a plurality of third voids through the memory cell material to the conductive layer at the first side of the pier, a position of each third void of the plurality of third voids corresponding to the respective metal layer of the stack of metal and oxide layers;
depositing, into the first cavity and into each third void of the plurality of third voids, a conductive material; and
etching the conductive material from the first cavity to form the plurality of first conductive paths.

18. The method of claim 14, wherein forming the plurality of second conductive paths comprises:
etching a plurality of third voids through the memory cell material to the conductive layer at the second side of the pier, a position of each third void of the plurality of third voids corresponding to the respective metal layer of the stack of metal and oxide layers;
depositing, into the second cavity and into each third void of the plurality of third voids, a conductive material; and
etching the conductive material from the second cavity to form the plurality of second conductive paths.

19. The method of claim 14, wherein forming the pier comprises:
etching a third cavity into the stack of nitride and oxide layers;
forming the memory cell material in the third cavity;
etching a fourth cavity into the memory cell material;
forming the conductive layer into the fourth cavity;
etching a fifth cavity into the conductive layer; and
depositing the core dielectric material into the fifth cavity.

20. The method of claim 19, further comprising:
performing, based at least in part on etching the third cavity, a nitride recess procedure to remove a respective portion of nitride from each nitride layer of the stack of nitride and oxide layers to form a plurality of voids in each nitride layer, wherein the memory cell material is formed within each void of the plurality of voids.

21. The method of claim 14, wherein the plurality of first memory cells are positioned at a third side of the pier and the plurality of second memory cells are positioned at a fourth side of the pier.

22. The method of claim 14, wherein the plurality of first memory cells and the plurality of second memory cells each comprise a first dielectric material, a second dielectric material, and a charge trapping layer between the first dielectric material and the second dielectric material.

23. A memory device formed by a process, comprising:
forming a pier in a stack comprising nitride layers and oxide layers, the pier comprising a core dielectric material, a conductive layer coupled with an outer surface of the core dielectric material, and a memory cell material coupled with an outer surface of the conductive layer;
etching, based at least in part on forming the pier, a pair of cavities into the stack of nitride layers and oxide layers, the pair of cavities comprising a first cavity and a second cavity, wherein the pier is positioned between the first cavity and the second cavity;
performing a metallization procedure to replace the nitride layers of the stack of nitride layers and oxide layers with a metal material to form a stack of metal layers and oxide layers;
forming a plurality of first conductive paths at a first side of the pier and a plurality of second conductive paths at a second side of the pier, the plurality of first conductive paths and the plurality of second conductive paths dividing the memory cell material into a plurality of first memory cells and a plurality of second memory cells, wherein a position of a respective first conductive path of the plurality of first conductive paths and a position of a respective second conductive path of the plurality of second conductive paths correspond to a respective metal layer of the stack of metal and oxide layers; and
forming a first pillar in the first cavity and a second pillar in the second cavity, wherein the first pillar is coupled with the conductive layer of the pier via the plurality of first conductive paths and the second pillar is coupled with the conductive layer of the pier via the plurality of second conductive paths.
